(19) United States
(12) Patent Application Publication
(10) Pub. No.: US 2012/0240984 A1
(43) Pub. Date: Sep. 27, 2012

(54) SOLAR CELL MODULE AND METHOD FOR MANUFACTURING THE SAME

(75) Inventors: Jae Hoon Kim, Seoul (KR); Jin Mun Ryu, Gyeonggi-do (KR); Seung Yun Oh, Gyeonggi-do (KR); In Taek Song, Gyeonggi-do (KR); Tae Young Kim, Seoul (KR)

(73) Assignee: SAMSUNG ELECTRO-MECHANICS CO., LTD.

(21) Appl. No.: 13/342,480

(22) Filed: Jan. 3, 2012

(30) Foreign Application Priority Data
Mar. 25, 2011 (KR) 10-2011-0026950

(51) Int. Cl. H01L 31/048; H01L 31/18; H01L 31/04

(52) U.S. Cl. 136/251; 136/259; 438/66; 257/E31.032

(57) ABSTRACT

A solar cell module comprises a rear contact solar cell in which positive (+) and negative (−) electrode patterns are alternately formed on a rear surface of a solar cell; insulating layers formed on both sides of the rear surface of the solar cell to be vertical to the electrode patterns; and a pair of conductive pattern bars that is disposed in a gap between both sides of the rear surface of the solar cell. Each conductive pattern bar includes a stem part formed on the each insulating layer and a plurality of branch parts extending from the stem part to be electrically connected to the same electrode patterns on the rear surface of the solar cell; and an encapsulant layer that protects the conductive pattern bars and at least the rear surface of the solar cell.

### CROSS REFERENCE(S) TO RELATED APPLICATIONS

This application claims the benefit under 35 U.S.C. Section 119 of Korean Patent Application Serial No. 10-2011-0026950, entitled “Solar Cell Module and Method for Manufacturing the Same” filed on Mar. 25, 2011, which is hereby incorporated by reference in its entirety into this application.

### BACKGROUND OF THE INVENTION

1. Technical Field

The present invention relates to a solar cell module and a method for manufacturing the same. More particularly, the present invention relates to a solar cell module and a method for manufacturing the same capable of simplifying a process and implementing a small size so as to be appropriate for small electronic devices by disposing conductive pattern bars in a gap between both sides of a rear surface of a solar cell without using a PCB.

2. Description of the Related Art

Recently, an interest and a market for new renewable energy has significantly grown due to an increase in oil price, depletion of fossil fuels, environmental problems, or the like. In particular, research and development of a solar cell as a clean energy source has actively progressed. Application fields of the solar cell have also been widely applied from power generation to general electronic devices. Further, solar energy conversion efficiency has considerably improved due to the development of technology and as a result, in a laboratory, a high efficiency cell having 23% or more conversion efficiency has been developed.

The solar cell is a device that converts light energy into electric energy using a photoelectric effect or a photovoltaic effect. The solar cell is classified into a silicon solar cell, a thin film solar cell, a dye sensitized solar cell, an organic polymer solar cell, or the like, according to the structure material thereof. Today, a silicon solar cell dominates the market. The silicon solar cell is generally configured of a semiconductor in which a p-n junction is made. Further, a solar cell module is formed by connecting the solar cells in parallel or in series according to required electric capacity.

The present invention relates to a solar cell module capable of being applied to small general electronic devices and a method for manufacturing the same. In particular, when a power supply of personal electronic products is exhausted or a battery cannot be used, the solar cell module may charge the battery using a solar cell in the daytime or may be used as an emergency power supply.

A silicon substrate type solar cell (a single crystalline or polycrystalline silicon substrate) according to the related art generally has a front and rear contact structure according to a contact structure and is mainly manufactured in a chip on board (COB) type.

FIG. 8 is a diagram schematically showing the solar cell module in the COB type according to the related art.

A method for manufacturing a solar cell module according to the related art shown in FIG. 8 includes dicing a solar cell 10 in a unit cell, die-attach-bonding the unit cell of the diced solar cell to a printed circuit board 14 (PCB) by a conductive epoxy bond 12, and connecting the solar cell with the PCB by a wire 11. Further, the solar cell module is manufactured by being molded with a transparent resin 13.

The solar cell module according to the related art is complex in a process and the manufacturing cost of the solar cell module is increased, due to the use of the PCB. In addition, it is difficult to implement production automation. In addition, it is inconvenient and difficult in manufacturing a module in which several solar cells are connected to each other in series by wire bonding, or the like.

### SUMMARY OF THE INVENTION

An object to the present invention is to provide a solar cell module and a method for manufacturing the same capable of implementing miniaturization, simplifying a process, and lowering production costs without using a PCB.

Another object of the present invention is to implement a small size, simplify a process, and lower production costs by attaching insulating layers to both sides of a rear surface of a solar cell using a rear contact solar cell and disposing conductive pattern bars on the insulating layers to be disposed in a gap between both sides of the rear surface of the solar cell.

Another object of the present invention is to simplify a process and improve production automation by manufacturing a solar cell module by attaching insulating layers and directly printing conductive pattern bars on the insulating layers and an electrode pattern on a rear surface of a solar cell.

According to an exemplary embodiment of the present invention, there is provided a solar cell module, including: a rear contact solar cell in which positive (+) and negative (−) electrode patterns are alternately formed on a rear surface of a solar cell; insulating layers that are formed on both sides of the rear surface of the solar cell to be vertical to the electrode patterns; a pair of conductive pattern bars that is disposed in a gap between both sides of the rear surface of the solar cell, wherein each conductive pattern bar includes a stem part formed on the each insulating layer and a plurality of branch parts extending from the stem part to be electrically connected to the same electrode patterns on the rear surface of the solar cell; and an encapsulant layer(s) that protects the conductive pattern bars and at least the rear surface of the solar cell.

The pair of conductive pattern bars may be disposed so that the branch parts of each conductive pattern bar extend to be opposite to that of other conductive pattern bar and the stem parts of the pair of conductive pattern bars may be extendedly formed in the same or opposite direction to each other so as to be connected to the outside.

The insulating layers may be subjected to the surface treatment according to any one of physical treatment using plasma, corona discharge, X-ray, laser, ion beam, or flame, an etching treatment using a potassium hydroxide solution, and a coating treatment using a primer material.

According to another exemplary embodiment of the present invention, there is provided a solar cell module, including: a plurality of rear contact solar cells in which positive (+) and negative (−) electrode patterns are alternately formed on rear surfaces thereof; insulating layers that are formed on both sides of the rear surface of the solar cell to be vertical to the electrode patterns; a plurality of conductive pattern bars of which a pair is disposed between both sides of the rear surfaces of each solar cell, wherein each conductive pattern bar includes a stem part formed on the each insulating layer in the solar cell and a plurality of branch parts extending from the stem part to electrically connect the same electrode patterns on the rear surface of the solar cell and is extendedly formed so as to connect the solar cell to other adjacent cells in series and to connect the branch parts in one other adjacent solar cell of each extended conductive pattern bar to opposite electrode patterns, such that all the plurality of solar cells are connected to each other in series; and an encapsulant layer(s) that protects the conductive pattern bars and at least the rear surfaces of the plurality of solar cells.

The pair of conductive pattern bars in each cell may be disposed so that the branch parts of each conductive pattern bar extend to be opposite to that of other conductive pattern bar, and the stem parts of the pair of conductive pattern bars in each solar cell may extend in each different direction, such that the each cell is connected to the different-directional adjacent cells in series.

A material of the conductive pattern bars may be a conductive material including any one of Pt, Au, Ag, Ni, Ti, and Cu.

The insulating layers may be subjected to the surface treatment according to any one of physical treatment using plasma, corona discharge, X-ray, laser, ion beam, or flame, an etching treatment using a potassium hydroxide solution, and a coating treatment using a primer material.

The encapsulant layers may include a lower encapsulant layer that protects the rear surfaces of the plurality of solar cells and a transparent upper encapsulant layer that protects front surfaces of the plurality of solar cells, a bottom portion of the lower encapsulant layer is provided with a back sheet layer that supports the plurality of solar cells, and a top portion of the upper encapsulant layer is provided with a transparent front cover layer.

The encapsulant layer(s) may be a transparent resin layer including at least one of EVA, epoxy, acrylic, melamine, polystyrene, and PVB.

The solar cell module may be used for small electronic devices.

According to another exemplary embodiment of the present invention, there is provided a method for manufacturing a solar cell module, including: (a) preparing a rear contact solar cell in which positive (+) and negative (−) electrode patterns are alternately formed on a rear surface of a solar cell; (b) forming insulating layers on both sides of the rear surface of the solar cell to be vertical to the electrode patterns; (c) forming a pair of conductive pattern bars that is disposed in a gap between both sides of the rear surface of the solar cell, wherein each conductive pattern bar includes a stem part formed on the each insulating layer and a plurality of branch parts extending from the stem part to be electrically connected to the same electrode patterns on the rear surface of the solar cell; and (d) forming a module by preparing encapsulant layers that protect front and rear surfaces of the solar cell on which the conductive pattern bars are formed, a front cover layer that is disposed on a top portion of the encapsulant layer on the front surface of the solar cell, and a back sheet that is disposed on a bottom portion of the encapsulant layer on the rear surface of the solar cell and heating and compressing them.

At step (b), the insulating layers may be formed by attaching insulating adhesive films that are subjected to the surface treatment according to any one of physical treatment using plasma, corona discharge, X-ray, laser, ion beam, or flame, an etching treatment using a potassium hydroxide solution, and a coating treatment using a primer material.

Step (c) may include: (c-1) forming the pair of conductive pattern bars including the stem part and the plurality of branch parts by applying a conductive material, and (c-2) sintering the applied conductive material at normal temperature using a photonic source.

At step (c-2), gamma ray, x-ray, ultraviolet ray, visible ray, infrared ray, microwave, radio wave, or a combination of at least some of thereof may be used as the photonic source.

According to another exemplary embodiment of the present invention, there is provided a method for manufacturing a solar cell module, including: (A) preparing a plurality of rear contact solar cells in which positive (+) and negative (−) electrode patterns are alternately formed on rear surfaces thereof; (B) forming insulating layers on both sides of the rear surface of the solar cell to be vertical to the electrode patterns; (C) forming a pair of conductive pattern bars in each solar cell between both sides of the rear surface of the solar cell, wherein each conductive pattern bar includes a stem part formed on the each insulating layer in the solar cell and a plurality of branch parts extending from the stem part to connect the same electrode patterns on the rear surface of the solar cell and is extendedly formed so that each solar cell is connected to other adjacent cells in series, and wherein the branch parts in other adjacent solar cell of the each extended conductive pattern bar are formed so as to be connected to opposite electrode patterns, such that all the plurality of solar cells are connected to each other in series; and (D) forming the module, in which the solar cells are connected to each other in series, by preparing encapsulant layers that protect front and rear surfaces of the plurality of solar cells on which the conductive pattern bars are formed, a front cover layer that is disposed on a top portion of the encapsulant layer on the front surface of the plurality of solar cells, and a back sheet that is disposed on a bottom portion of the encapsulant layer on the rear surfaces of the plurality of solar cells and heating and compressing them.

At step (B), the insulating layers may be formed by attaching an insulating adhesive film that is subjected to the surface treatment according to any one of physical treatment using plasma, corona discharge, X-ray, laser, ion beam, or flame, an etching treatment using a potassium hydroxide solution, and a coating treatment using a primer material.

Step (C) may include: (C-1) forming the stem part and the plurality of branch parts of the conductive pattern bars by applying a conductive material; and (C-2) sintering the applied conductive material at normal temperature using a photonic source.

At step (C-2), gamma ray, x-ray, ultraviolet ray, visible ray, infrared ray, microwave, radio wave, or a combination of at least some of thereof may be used as the photonic source.

The encapsulant layers may be a transparent resin material including at least one of EVA, epoxy, acrylic, melamine, polystyrene, and PVB.

Although not specifically stated as an aspect of the present invention, exemplary embodiments of the present invention according to possible various combinations of above-mentioned technical characteristics may be supported by the following specific exemplary embodiments and may be obviously implemented by those skilled in the art.

### BRIEF DESCRIPTION OF THE DRAWINGS

FIG. 1 is a diagram schematically showing a cross section of a solar cell module according to an exemplary embodiment of the present invention;

FIG. 2 is a diagram schematically showing a rear surface of the solar cell module according to the exemplary embodiment of the present invention;

FIG. 3 is a diagram schematically showing the rear surfaces of the solar cell modules connected in series according to another exemplary embodiment of the present invention;

FIG. 4 is a diagram schematically showing a side cross section of the solar cell module connected in series according to another exemplary embodiment of the present invention;

FIG. 5 is a flow chart schematically showing a method for manufacturing a solar cell module according to another exemplary embodiment of the present invention;

FIG. 6 is a flow chart schematically showing a method for manufacturing a solar cell module according to another exemplary embodiment of the present invention;

FIG. 7 is a flow chart schematically showing some processes of a method for manufacturing a solar cell module according to another exemplary embodiment of the present invention; and

FIG. 8 is a diagram schematically showing a solar cell module in the COB type according to the related art.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

It will be understood that when an element is referred to as simply being “coupled to” or “connected to” another element rather than being “directly coupled to” or “directly connected to” another element in the present description, it can be directly connected with the other element or may be connected with another element, having other element coupled or connected therebetween, as long as it is not contradictory to the description or is opposite to the concept of the present invention

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

First, a solar cell module according to an exemplary embodiment of the present invention will be described with reference to the accompanying drawings.

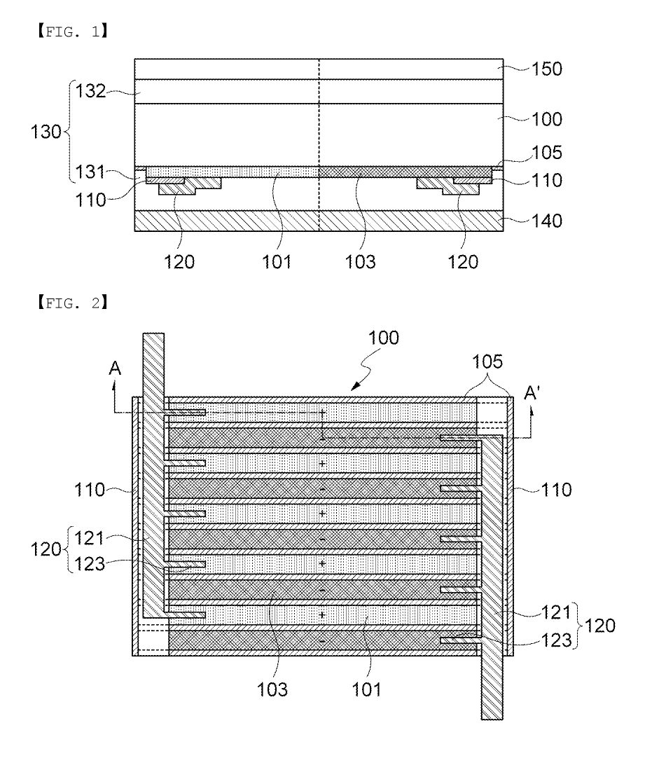

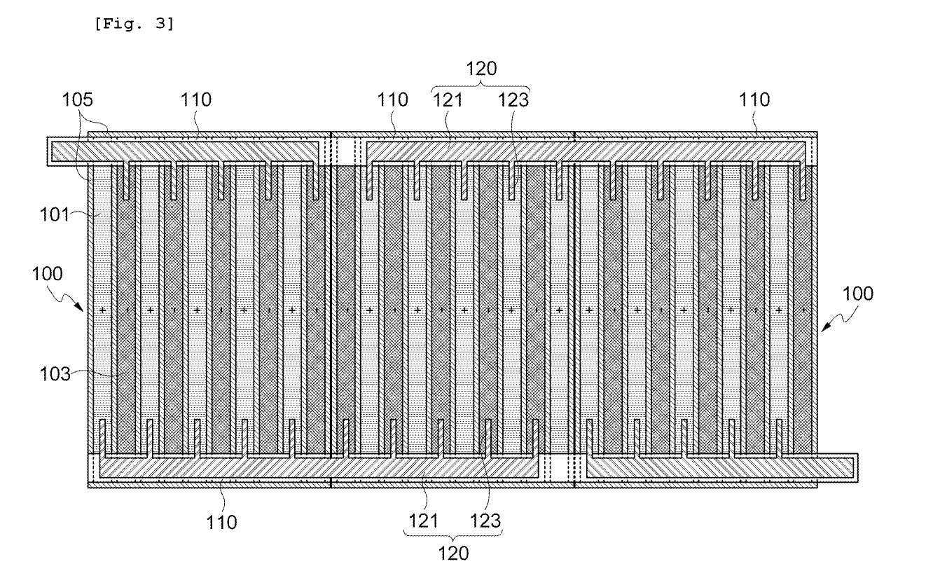

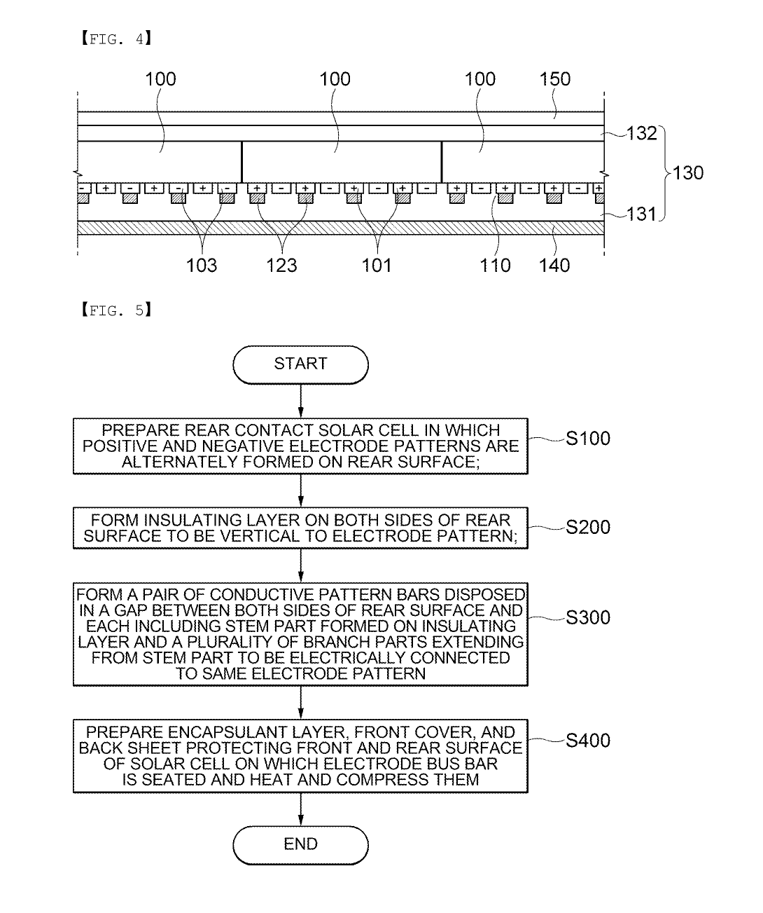

FIG. 1 is a diagram schematically showing a cross section of a solar cell module according to an exemplary embodiment of the present invention, FIG. 2 is a diagram schematically showing a rear surface of the solar cell module according to the exemplary embodiment of the present invention, FIG. 3 is a diagram schematically showing the rear surfaces of the solar cell modules connected in series according to another exemplary embodiment of the present invention, and FIG. 4 is a diagram schematically showing a side cross section of the solar cell module connected in series according to another exemplary embodiment of the present invention.

Referring to FIGS. 1 and 2, a solar cell module according to an exemplary embodiment of the present invention will be described in detail. Unlike FIG. 2, FIG. 1 shows a cross section including an encapsulant layer 130, a back sheet layer 140, or the like, and corresponds to a portion in which section A-A′ of FIG. 2 is cut. FIG. 2 does not show the encapsulant layer and the back sheet layer added to the rear surface of the solar cell so as to show in more detail a rear structure of the solar cell.

Referring to FIGS. 1 and 2, an exemplary embodiment of the present invention will be described. The solar cell module according to the exemplary embodiment of the present invention is configured to include a rear contact solar cell 100, insulating layers 110, a pair of conductive pattern bars 120, and an encapsulant layer 131 for protecting at least the rear surface of the solar cell 100 and the conductive pattern bars 120 Preferably, as shown in FIG. 1, the back sheet layer 140 may be further provided on the bottom portion of the encapsulant layer 131. More preferably, the encapsulant layer 131 for protecting the rear surface of the solar cell 100 and the encapsulant layer 132 for protecting the front surface of the solar cell 100 may be further provided.

The rear contact solar cell 100 means the solar cell 100 in which both the positive (+) and negative (−) electrodes 101 and 103 are formed on the rear surface thereof. As shown in FIG. 2, the positive (+) and negative (−) electrode patterns 101 and 103 are alternately formed on the rear contact solar cell 100 according to the exemplary embodiment of the present invention. Although the electrode patterns 101 and 103 penetrating through an oxide layer 105 are not shown, they are connected to a p-type impurity doping layer or an n-type impurity doping layer, for example, in an area of the solar cell, for example, a silicon substrate layer.

The insulating layers 110 are formed at both sides of the rear surface of the solar cell to be vertical to the electrode patterns. Preferably, the insulating layer 110 is made of an insulating adhesive film. The insulating layer 110 may be subjected to several surface treatments. Preferably, in an exemplary embodiment of the present invention, the insulating layer 110 is subjected to the surface treatment according to any one of physical treatment using plasma, corona discharge, X-ray, laser, ion beam, or flame, an etching treatment using a potassium hydroxide solution, and a coating treatment using a primer material.

Referring to FIGS. 1 and 2, the pair of conductive pattern bars 120 is disposed in a gap between both sides of the rear surface of the solar cell 100. Each conductive pattern bar 120 includes stem part 121 and a plurality of branch part 123 as shown in FIG. 2. The stem part 121 are formed on the insulating layer 110 and thus, are not connected to the electrode on the rear surface of the solar cell 100. The plurality of branch parts 123 are electrically connected to the same electrode patterns 101 and 103 on the rear surface of the solar cell by extending from the stem part 121. Preferably, the conductive pattern bars 120 may be formed by printing and coating and may be fixedly disposed using a metal pattern manufactured by etching, or the like. Preferably, in order to implement process simplification and production automation, the conductive pattern bars 120 may be formed by a printing or coating method.

Preferably, according to an exemplary embodiment of the present invention, the pair of conductive pattern bars 120 is disposed so that each branch part 123 extends to be opposite to each other. In addition, the stem part 121 of each conductive pattern bar 120 may be extendedly formed in the same or opposite direction to each other so as to be connected to the outside.

Preferably, according to another exemplary embodiment of the present invention, a material of the pair of conductive pattern bars 120 is a conductive material including any one of Pt, Au, Ag, Ni, Ti, and Cu. Preferably, the conductive pattern bars 120 are formed by printing or coating the electrode using, for example, inkjet printing, screen printing, or the like. After the printing, for example, the inkjet or screen printing or the coating, the conductive pattern bars 120 are sintered at normal temperature using a photonic source. Preferably as the photonic source, gamma ray, x-ray, ultraviolet ray, visible ray, infrared ray, microwave, radio wave, or a combination thereof may be used. A heat treatment process can be performed in an oven, or the like, but a normal temperature process is more preferable since warpage of a cell may occur due to the difference in thermal expansion coefficients during the heat treatment process.

In the exemplary embodiment of the present invention, the encapsulant layer 131 protects the pair of conductive pattern bars 120 and at least the rear surface of the solar cell 100. Preferably, referring to FIG. 1, according to another exemplary embodiment of the present invention, the encapsulant layer 130 forming a passivation layer is configured to include a lower encapsulant layer 131 protecting the rear surface of the solar cell 100 and a transparent upper encapsulant layer 132 protecting the front surface of the solar cell 100. Preferably, the encapsulant layer 130 is made of a transparent resin layer including at least one of EVA, epoxy, acrylic, melamine, polystyrene, and PVB.

According to another exemplary embodiment of the present invention, the back sheet layer 140 of FIG. 1 is disposed on the bottom portion of the encapsulant layer 131 protecting at least the rear surface of the solar cell 100 to support the solar cell 100. In detail, according to another exemplary embodiment of the present invention, referring to FIG. 1, the back sheet layer 140 is disposed on the bottom portion of the lower encapsulant layer 131.

Preferably, according to another exemplary embodiment of the present invention, referring to FIG. 1, a transparent front cover layer 150 is provided on the top portion of the upper encapsulant layer 132. Preferably, the front cover layer 150 is made of a transparent front sheet or a cover glass.

Preferably, the above-mentioned solar cell modules are used for small electronic devices, such as, for example, mobile devices, or the like.

Next, the solar cell module in which the plurality of solar cells 100 according to the exemplary embodiment of the present invention are connected to each other in series will be described in detail with reference to FIGS. 3 and 4. Voltage that can be generally generated by the solar cell 100 is affected by the type of semiconductor material used. Generally, about 0.5 V is generated in the case of using silicon. Therefore, the module according to the exemplary embodiment of the present invention manufactured by connecting the solar cells 100 to each other in series are used so as to obtain higher voltage. FIG. 3 does not show the encapsulant layer 131 (see FIG. 4) added on the rear surfaces of the solar cells 100 and the back sheet layer 140 (see FIG. 4) so as to show in more detail the rear structure of the solar cells 100 connected to each other in series.

Referring to FIGS. 3 and 4, the solar cell module according to the exemplary embodiment of the present invention is configured to include the plurality of rear contact solar cells 100, the insulating layers 110, the plurality of conductive pattern bars 120, and the encapsulant layer 131 for protecting the rear surface of the plurality of cells 100 and the plurality of conductive pattern bars 120. Preferably, according to the exemplary embodiment of the present invention, referring to FIG. 4, the back sheet layer 140 is further provided. The description of the rear contact solar cell 100 will refer to the above description.

The insulating layer 110 is formed at both sides of the rear surface of each cell 100 (solar cell) so as to be vertical to the electrode patterns 101 and 103. Preferably, the insulating layer 110 is made of an insulating adhesive film. The insulating layer 110 may be subjected to several surface treatments. Preferably, in an exemplary embodiment of the present invention, the insulating layer 110 is subjected to the surface treatment according to any one of physical treatment using plasma, corona discharge, X-ray, laser, ion beam, or flame, an etching treatment using a potassium hydroxide solution, and a coating treatment using a primer material.

Next, the plurality of conductive pattern bars 120 will be described with reference to FIGS. 3 and 4. The pair of conductive pattern bars 120 is disposed between both sides of the rear surfaces of each solar cell 100. Preferably, the conductive pattern bars 120 may be formed by printing and coating and may be fixedly disposed using a metal pattern manufactured by etching, or the like. Preferably, in order to implement process simplification and production automation, the conductive pattern bars 120 may be formed by a printing or coating method. Each conductive pattern bar 120 in each solar cell 100 includes the stem part 121 and the plurality of branch parts 123. The stem part 121 of each conductive pattern bar 120 in each solar cell 100 are formed on the same insulating layer 110 within the solar cell. In addition, the plurality of branch parts 123 are electrically connected to the same electrode patterns 101 and 103 on the rear surface of the solar cell 100 by extending from the stem part 121. Referring to FIG. 3, the pair of conductive pattern bars 120 in each solar cell 100 are extendedly formed so that each solar cell 100 is connected to other adjacent solar cells 100 in series. The branch parts 123 in other solar cells 100 of each conductive pattern bar 120 extending to other solar cells 100 are formed to be connected to the opposite electrode patterns 103 and 101. In this case, each conductive pattern bar 120 connects two solar cells 100 in series by connecting the plurality of branch parts 123 within the single solar cell 100 and the plurality of branch parts 123 within the other solar cell 100 to the electrode patterns 103 and 101 opposite to each other. Therefore, all of the plurality of solar cells 100 are generally connected to each other in series.

Preferably, according to the exemplary embodiment of the present invention, the pair of conductive pattern bars 120 in each solar cell 100 is disposed so that each branch part 123 extends to be opposite to each other. In addition, the stem part 121 of the conductive pattern bars 120 in each solar cell 100 each extend in different directions so as to be serially connected with the adjacent solar cells 100 in different directions.

Preferably, according to another exemplary embodiment of the present invention, a material of the pair of conductive pattern bars 120 is a conductive material including any one of Pt, Au, Ag, Ni, Ti, and Cu. Preferably, the conductive pattern bars 120 are formed by printing or coating the electrode using, for example, the inkjet printing, the screen printing, or the like. After the printing, for example, the inkjet or screen printing or the coating, the conductive pattern bars 120 are sintered at normal temperature using a photonic source. Preferably, as the photonic source, gamma ray, x-ray, ultraviolet ray, visible ray, infrared ray, microwave, radio wave, or a combination thereof may be used. A heat treatment process can be performed in an oven, or the like, but a normal temperature process is more preferable since warpage of a solar cell may occur due to the difference in thermal expansion coefficients during the heat treatment process.

Referring to FIG. 4, in the exemplary embodiment of the present invention, the encapsulant layer 131 protects the plurality of conductive pattern bars 120 (see FIG. 3) and the plurality of rear contact solar cells 100. Preferably, according to another exemplary embodiment of the present invention, the encapsulant layer 130 forming a passivation layer is configured to include the lower encapsulant layer 131 protecting the rear surfaces of the plurality of solar cells 100 and the transparent upper encapsulant layer 132 protecting the front surfaces of the plurality of solar cells 100. Preferably, the encapsulant layer 130 is made of a transparent resin layer including at least one of EVA, epoxy, acrylic, melamine, polystyrene, and PVB.

Preferably, according to another exemplary embodiment of the present invention, the back sheet layer 140 of FIG. 4 is disposed on the bottom portion of the encapsulant layer 130 to support the plurality of rear contact solar cells 100. Preferably, referring to FIG. 4, the back sheet layer 140 is disposed on the bottom portion of the lower encapsulant layer 131.

Preferably, according to another exemplary embodiment of the present invention, referring to FIG. 4, the transparent front cover layer 150 is provided on the top portion of the upper encapsulant layer 132. Preferably, the front cover layer 150 may be formed of a transparent front sheet or a cover glass.

Preferably, the above-mentioned solar cell modules are used for small electronic devices, such as, for example, mobile devices, or the like.

Next, a method for manufacturing a solar cell module according to another exemplary embodiment of the present invention will be described with reference to the accompanying drawings. The exemplary embodiments of the present invention is one of the methods for manufacturing a solar cell module as described above and therefore, like components are denoted by like reference numerals in FIGS. 1 to 4 and is to be understood with reference to the detailed descriptions of the above-mentioned exemplary embodiments of the present invention.

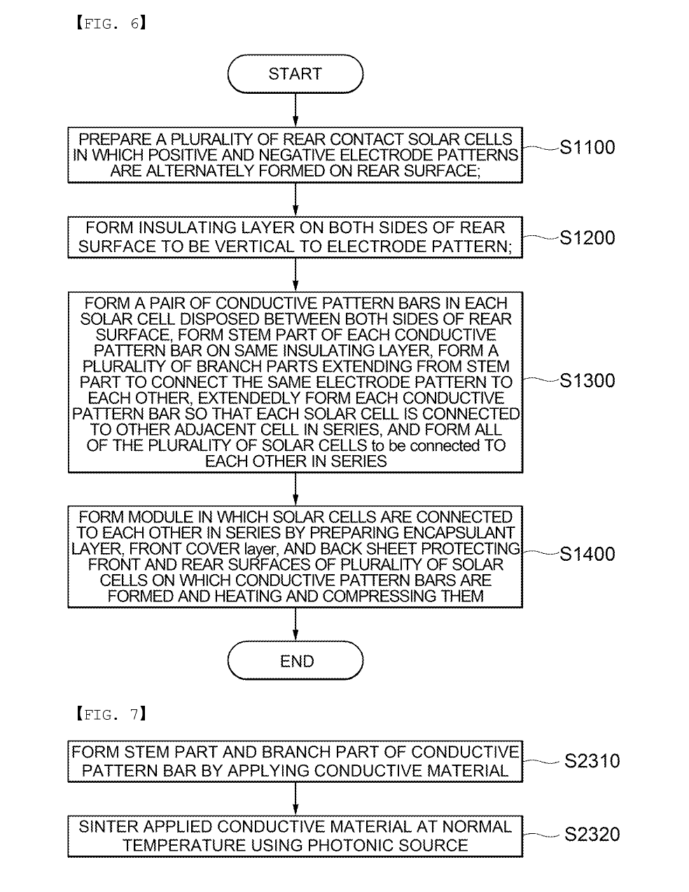

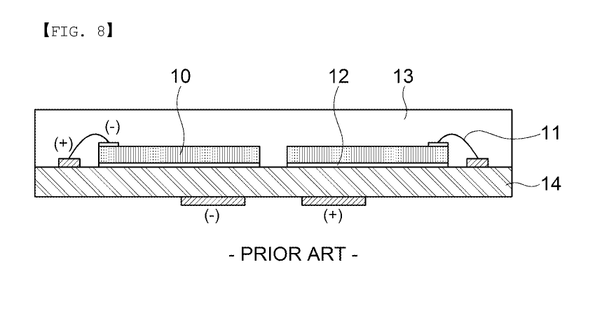

FIG. 5 is a flow chart schematically showing a method for manufacturing a solar cell module according to another exemplary embodiment of the present invention, FIG. 6 is a flow chart schematically showing a method for manufacturing a solar cell module according to another exemplary embodiment of the present invention, and FIG. 7 is a flow chart schematically showing some processes of a method for manufacturing a solar cell module according to another exemplary embodiment of the present invention.

Describing a method for manufacturing a solar cell module according to an exemplary embodiment of the present invention with reference to FIG. 5, the method includes subsequent steps (a) to (d) (S100 to S400). The exemplary embodiment of the present invention refers to the exemplary embodiment of the present invention of the solar cell module shown in FIGS. 1 and 2.

At step (a) (S100), the rear contact solar cell 100 in which the positive (+) and negative (−) electrode patterns 101 and 103 are alternately formed on the rear surface of the solar cell 100 is prepared.

Next, at step (b) (S200), the insulating layer 110 are formed on both sides of the rear surface of the solar cell 100 to be vertical to the electrode patterns 101 and 103 of the solar cell 100. Preferably, according to the exemplary embodiment of the present invention, the insulating layer 110 is formed by attaching the insulating adhesive film.

The insulating layer 110 may be subjected to several surface treatments. Preferably, according to the exemplary embodiment of the present invention, the insulating layer 110, for example, the insulating adhesive film is subjected to the surface treatment according to any one of physical treatment using plasma, corona discharge, X-ray, laser, ion beam, or flame, an etching treatment using a potassium hydroxide solution, and a coating treatment using a primer material to be attached to both sides of the rear surface of the solar cell 100 to be vertical to the electrode patterns 101 and 103 of the solar cell 100.

Next, at step (C) (S300), the pair of prepared conductive pattern bars 120 is disposed within the gap between both sides of the rear surface of the solar cell. Preferably, the conductive pattern bars 120 may be formed by printing and coating and may be fixedly disposed using a metal pattern manufactured by etching, or the like. Preferably, in order to implement process simplification and production automation, the conductive pattern bars 120 may be formed by a printing or coating method. The conductive pattern bar 120 includes the stem part 121 and the plurality of branch parts 123. The stem part 121 is formed on the insulating layer 110. In this case, the stem part 121 is not connected to the electrode on the rear surface of the solar cell 100. The plurality of branch parts 123 are formed to be electrically connected to the same electrode patterns 101 and 103 on the rear surface of the solar cell 100 by extending from the stem part 121.

Preferably, the pair of conductive pattern bars 120 is disposed so that each branch part 123 extends to be opposite to each other. In addition, the stem part 121 of each conductive pattern bar 120 may be extendedly formed in the same or opposite direction to each other so as to be connected to the outside.

Preferably, a material of the pair of conductive pattern bars 120 is a conductive material including any one of Pt, Au, Ag, Ni, Ti, and Cu.

Step (c) (S300) will be described in detail with reference to FIG. 7.

Referring to FIG. 7, according to the exemplary embodiment of the method invention, step (c) (S300) includes: (c-1) applying a conductive material (S2310), and (c-2) normal temperature sintering (S2330).

At step (c-1) (S2310), the pair of conductive pattern bars 120 including the stem part 121 and the plurality of branch parts 123 is formed by applying the conductive material. Preferably, the conductive pattern bars 120 are formed by printing or coating the electrode using, for example, the inkjet printing, the screen printing, or the like. Preferably, the electrode is printed by the inkjet printing.

Further, at step (c-2) (S2330), the applied conductive material is sintered at normal temperature using the photonic source. The heat treatment process can be performed in an oven, or the like, but the normal temperature process is more preferable since warpage of a cell may occur due to the difference in the thermal expansion coefficients during the heat treatment process.

Preferably, according to the exemplary embodiment of the present invention, at the above-mentioned step (c-2) (S2330), as the photonic source, gamma ray, x-ray, ultraviolet ray, visible ray, infrared ray, microwave, radio wave, or a combination of at least some thereof may be used.

Further, at step (d) (S400), the encapsulant layer 130 for protecting the front and rear surfaces of the solar cell 100 on which the conductive pattern bars 120 are formed, the front cover layer 150 disposed on the top portion of the encapsulant layer 130 on the front surface of the solar cell 100, the back sheet 140 disposed on the bottom portion of the encapsulant layer 130 on the rear surface of the solar cell 100 are prepared and are heated and compressed, thereby forming the module. A heat fusing technology heating and compressing may be implemented according to a technology known in the art and therefore, the detailed description thereof will be omitted.

Preferably, the encapsulant layer 130 is made of a transparent resin material including any one of EVA, epoxy, acrylic, melamine, polystyrene, or PVB.

Preferably, the solar cell modules manufactured according to the exemplary embodiment of the present invention are used for small electronic devices, such as, for example, mobile devices, or the like.

Voltage that can be generally generated by the solar cell 100 is affected by type of semiconductor material used. Generally, about 0.5 V is generated in the case of using silicon. Therefore, the solar cells connected to each other in series are used so as to obtain higher voltage. The solar cells may be manufactured by connecting to each other in series as follows.

Describing a method for manufacturing a solar cell module in which the plurality of solar cells are connected to each other in series according to an exemplary embodiment of the present invention with reference to FIG. 6, the method includes subsequent steps (A) to (D) (S1100 to S1400). The exemplary embodiment of the present invention refers to the exemplary embodiment of the present invention of the solar cell module shown in FIGS. 3 and 4.

At step (A) (S1100), the plurality of rear contact solar cells 100 in which the positive (+) and negative (−) electrode patterns 101 and 103 are alternately formed on the rear surface of the solar cell 100 are prepared.

Next, at step (B) (S1200), the insulating layers 110 are formed on both sides of the rear surface of the solar cell to be vertical to the electrode patterns 101 and 103 of each of the solar cells 100. Preferably, according to the exemplary embodiment of the present invention, the insulating layer 110 is formed by attaching the insulating adhesive film. The insulating layer 110 may be subjected to several surface treatments.

Preferably, according to the exemplary embodiment of the present invention, the insulating layer 110, for example, the insulating adhesive film is subjected to the surface treatment according to any one of physical treatment using plasma, corona discharge, X-ray, laser, ion beam, or flame, an etching treatment using a potassium hydroxide solution, and a coating treatment using a primer material to be attached to both sides of the rear surface of the solar cell 100 to be vertical to the electrode patterns 101 and 103 of the solar cell 100.

Next, at step (C) (S1300), the pair of conductive pattern bars 120 for each solar cell 100 is disposed between both sides of the rear surface of the solar cell 100. Preferably, the conductive pattern bars 120 may be formed by printing and coating and may be fixedly disposed using a metal pattern manufactured by etching, or the like. Preferably, in order to implement process simplification and production automation, the conductive pattern bars 120 may be formed by a printing or coating method. Each conductive pattern bar 120 in each solar cell 100 includes the stem part 121 and the plurality of branch parts 123. Referring to FIG. 6, at step (C) (S1300), the stem part 121 of each conductive pattern bar 120 is formed on the same insulating layer 110 on the rear surface of the solar cell 100 and the plurality of branch parts 123 extending from the stem part 121 are formed to connect the same electrode patterns 101 and 103 on the rear surface of the solar cell 100 to each other. Each conductive pattern bar 120 in each solar cell 100 is extendedly formed to connect each solar cell 100 to the other adjacent cells 100 in series. The branch parts 123 in other solar cells 100 of each conductive pattern bar 120 extending to other solar cells 100 are formed to be connected to the opposite electrode patterns 103 and 101. In this case, each conductive pattern bar 120 connects two solar cells 100 in series by connecting the plurality of branch parts 123 within the single solar cell 100 and the plurality of branch parts 123 within the other solar cell 100 to the electrode patterns 103 and 101 opposite to each other. Accordingly, the branch parts 123 in other solar cells 100 of each conductive pattern bar 120 extending so as to connect all the plurality of solar cells 100 to each other in series are formed to be connected to the opposite electrode patterns 103 and 101.

Preferably, the pair of conductive pattern bars 120 in each solar cell 100 is disposed so that each branch part 123 extends to be opposite to each other. In addition, the stem part 121 of each conductive pattern bar 120 may be extendedly formed in the opposite direction to each other so as to be connected to the outside.

Preferably, a material of the pair of conductive pattern bars 120 is a conductive material including any one of Pt, Au, Ag, Ni, Ti, and Cu.

Describing another exemplary embodiment of the present invention with reference to FIG. 7, the above-mentioned step (C) (S1300) according to FIG. 6 includes: (C-1) applying a conductive material (S2310), and (C-2) normal temperature sintering (S2330). At step (C-1) (S2310) of FIG. 7, the plurality of conductive pattern bars 120 including the stem part 121 and the plurality of branch parts 123 is formed by applying the conductive material. Preferably, the conductive pattern bars 120 are formed by printing or coating the electrode using, for example, the inkjet printing, the screen printing, or the like, preferably, using the inkjet printing. Further, at step (C-2) (S2330), the applied conductive material is sintered at normal temperature using the photonic source. The heat treatment process can be performed in an oven, or the like, but the normal temperature process as in the exemplary embodiment of the present invention is more preferable since warpage of the cell may occur due to the difference in the thermal expansion coefficients.

Preferably, according to another exemplary embodiment of the present invention, at the above-mentioned step (C-2) (S2330), as the photonic source, gamma ray, x-ray, ultraviolet ray, visible ray, infrared ray, microwave, radio wave, or a combination of at least some thereof may be used.

Further, at step (D) (S1400), the encapsulant layer 130 for protecting the front and rear surfaces of the plurality of solar cells 100 on which the plurality of conductive pattern bars 120 are formed, the front cover layer 150 disposed on the top portion of the encapsulant layer 130 on the front surface of the plurality of solar cells 100, the back sheet 140 disposed on the bottom portion of the encapsulant layer 130 on the rear surface of the plurality of solar cells 100 are prepared and are heated and compressed, thereby forming the module in which the solar cells 100 are connected to each other in series. Preferably, according to another exemplary embodiment of the present invention, the encapsulant layer 130 is made of a transparent resin material including any one of EVA, epoxy, acrylic, melamine, polystyrene, or PVB.

Preferably, the solar cell modules manufactured according to the exemplary embodiment of the present invention are used for small electronic devices, such as, for example, mobile devices, or the like.

As set forth above, the exemplary embodiment of the present invention can implement a small size, simplify the process, and lower the production costs by attaching the insulating layers on both sides of the rear surface of the solar cell using the rear contact solar cell and disposing the conductive pattern bars in the gap between both sides of the rear surface of the solar cell.

In particular, the exemplary embodiment of the present invention can simplify the process and lower the production costs of the solar cell module since the PCB used in the solar cell module according to the related art is not used.

In addition, the exemplary embodiment of the present invention can simplify the process and improve production automation by manufacturing the solar cell module by attaching the insulating layers and directly printing the conductive pattern bars on the insulating layers and the electrode pattern on the rear surface of the solar cell.

In addition, the exemplary embodiment of the present invention can simplify the process, lower the production costs, and improve production automation even in the case of manufacturing the module with the plurality of cells connected in series, by manufacturing the solar cell module by attaching the insulating layers to the plurality of rear contact solar cells and printing the conductive pattern bars thereon.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. While this invention has been described in connection with what is presently considered to be practical exemplary embodiments, it is to be understood that the invention is not limited to the disclosed embodiments. Therefore, it will be apparent to those skilled in the art that various modifications, substitutions and equivalents can be made in the present invention without departing from the spirit or scope of the inventions.

What is claimed is:

1. A solar cell module, comprising:
a rear contact solar cell in which positive (+) and negative (−) electrode patterns are alternately formed on a rear surface thereof;
insulating layers that are formed on both sides of the rear surface of the solar cell to be vertical to the electrode patterns;
a pair of conductive pattern bars that is disposed in a gap between both sides of the rear surface of the solar cell, wherein each conductive pattern bar includes a stem part formed on the each insulating layer and a plurality of branch parts extending from the stem part to be electrically connected to the same electrode patterns on the rear surface of the solar cell; and
an encapsulant layer that protects the conductive pattern bars and at least the rear surface of the solar cell.

2. The solar cell module according to claim 1, wherein the pair of conductive pattern bars is disposed so that the branch parts of each conductive pattern bar extend to be opposite to that of other conductive pattern bar, and
the stem parts of the pair of conductive pattern bars are extendedly formed in the same or opposite direction to each other so as to be connected to the outside.

3. The solar cell module according to claim 1, wherein the insulating layers are subjected to the surface treatment according to any one of physical treatment using plasma, corona discharge, X-ray, laser, ion beam, or flame, an etching treatment using a potassium hydroxide solution, and a coating treatment using a primer material.

4. A solar cell module, comprising:
a plurality of rear contact solar cells in which positive (+) and negative (−) electrode patterns are alternately formed on rear surfaces thereof;
insulating layers that are formed on both sides of the rear surface of the solar cell to be vertical to the electrode patterns;
a plurality of conductive pattern bars of which a pair is disposed between both sides of the rear surfaces of each solar cell, wherein each conductive pattern bar includes a stem part formed on the each insulating layer in the solar cell and a plurality of branch parts extending from the stem part to electrically connect the same electrode patterns on the rear surface of the solar cell and is extendedly formed so as to connect the solar cell to other adjacent cells in series and to connect the branch parts in one other adjacent solar cell of each extended conductive pattern bar to opposite electrode patterns, such that all the plurality of solar cells are connected to each other in series; and
an encapsulant layer that protects the conductive pattern bars and at least the rear surfaces of the plurality of solar cells.

5. The solar cell module according to claim 4, wherein the pair of conductive pattern bars in each cell is disposed so that the branch parts of each conductive pattern bar extend to be opposite to that of other conductive pattern bar, and
the stem parts of the pair of conductive pattern bars in each solar cell are extended in each different direction, such that each solar cell is connected to the different-directional adjacent cells in series.

6. The solar cell module according to claim 4, wherein a material of the conductive pattern bars is a conductive material including any one of Pt, Au, Ag, Ni, Ti, and Cu.

7. The solar cell module according to claim 4, wherein the insulating layers are subjected to the surface treatment according to any one of physical treatment using plasma, corona discharge, X-ray, laser, ion beam, or flame, an etching treatment using a potassium hydroxide solution, and a coating treatment using a primer material.

8. The solar cell module according to claim 4, wherein the encapsulant layer includes a lower encapsulant layer that protects the rear surfaces of the plurality of solar cells and a transparent upper encapsulant layer that protects front surfaces of the plurality of solar cells,
a bottom portion of the lower encapsulant layer is provided with a back sheet layer that supports the plurality of solar cells, and
a top portion of the upper encapsulant layer is provided with a transparent front cover layer.

9. The solar cell module according to claim 4, wherein the encapsulant layer is a transparent resin layer including at least one of EVA, epoxy, acrylic, melamine, polystyrene, and PVB.

10. The solar cell module according to claim 1, wherein the solar cell module is used for small electronic devices.

11. The solar cell module according to claim 4, wherein the solar cell module is used for small electronic devices.

12. A method for manufacturing a solar cell module, comprising:
(a) preparing a rear contact solar cell in which positive (+) and negative (−) electrode patterns are alternately formed on a rear surface of a solar cell;
(b) forming insulating layers on both sides of the rear surface of the solar cell to be vertical to the electrode patterns;
(c) forming a pair of conductive pattern bars that is disposed in a gap between both sides of the rear surface of the solar cell, wherein each conductive pattern bar includes a stem part formed on the each insulating layer and a plurality of branch parts extending from the stem part to be electrically connected to the same electrode patterns on the rear surface of the solar cell; and
(d) forming a module by preparing encapsulant layers that protect front and rear surfaces of the solar cell on which the conductive pattern bars are formed, a front cover layer that is disposed on a top portion of the encapsulant layer on the front surface of the solar cell, and a back sheet that is disposed on a bottom portion of the encapsulant layer on the rear surface of the solar cell and heating and compressing them.

13. The method according to claim 12, wherein at step (b), the insulating layers are formed by attaching insulating adhesive films that are subjected to the surface treatment according to any one of physical treatment using plasma, corona discharge, X-ray, laser, ion beam, or flame, an etching treatment using a potassium hydroxide solution, and a coating treatment using a primer material.

14. The method according to claim 12, wherein step (c) includes:
(c-1) forming the pair of conductive pattern bars including the stem part and the plurality of branch parts by applying a conductive material; and
(c-2) sintering the applied conductive material at normal temperature using a photonic source.

15. The method according to claim 14, wherein at step (c-2), gamma ray, x-ray, ultraviolet ray, visible ray, infrared ray, microwave, radio wave, or a combination of at least some of thereof is used as the photonic source.

16. A method for manufacturing a solar cell module, comprising:
(A) preparing a plurality of rear contact solar cells in which positive (+) and negative (−) electrode patterns are alternately formed on rear surfaces thereof;
(B) forming insulating layers on both sides of the rear surface of the solar cell to be vertical to the electrode patterns;
(C) forming a pair of conductive pattern bars in each solar cell disposed between both sides of the rear surface of the solar cell, wherein each conductive pattern bar includes a stem part formed on the each insulating layer in the solar cell and a plurality of branch parts extending from the stem part to connect the same electrode patterns on the rear surface of the solar cell and is extendedly formed so that each solar cell is connected to other adjacent cells in series, and wherein the branch parts in other adjacent solar cell of the each extended conductive pattern bar are formed so as to be connected to opposite electrode patterns, such that all the plurality of solar cells are connected to each other in series; and
(D) forming the module, in which the solar cells are connected to each other in series, by preparing encapsulant layers that protect front and rear surfaces of the plurality of solar cells on which the conductive pattern bars are formed, a front cover layer that is disposed on a top portion of the encapsulant layer on the front surfaces of the plurality of the solar cells, and a back sheet that is disposed on a bottom portion of the encapsulant layer on the rear surfaces of the plurality of solar cells and heating and compressing them.

17. The method according to claim 16, wherein at step (B), the insulating layers are formed by attaching insulating adhesive films that are subjected to the surface treatment according to any one of physical treatment using plasma, corona discharge, X-ray, laser, ion beam, or flame, etching treatment using a potassium hydroxide solution, and coating treatment using a primer material.

18. The method according to claim 16, wherein step (C) includes:
(C-1) forming the stem part and the plurality of branch parts of the conductive pattern bars by applying a conductive material; and
(C-2) sintering the applied conductive material at normal temperature using a photonic source.

19. The method according to claim 18, wherein at step (C-2), gamma ray, x-ray, ultraviolet ray, visible ray, infrared ray, microwave, radio wave, or a combination of at least some of thereof is used as the photonic source.

20. The method according to claim 12, wherein the encapsulant layers are a transparent resin material including at least one of EVA, epoxy, acrylic, melamine, polystyrene, and PVB.
